(19) United States
(12) Patent Application Publication
(10) Pub. No.: US 2007/0018302 A1
(43) Pub. Date: Jan. 25, 2007

(54) Planar light source device and display device provided with the same

(75) Inventors: Hae-Il Park, Seoul (KR); Sang-Yu Lee, Yongin-si (KR); Jin-Seob Byun, Seoul (KR)

Correspondence Address: F. CHAU & ASSOCIATES, LLC, 130 WOODBURY ROAD, WOODBURY, NY, 11797, US

(73) Assignee: Samsung Electronics Co., LTD., Suwon-si (KR)

(21) Appl. No.: 11/489,042

(22) Filed: Jul. 19, 2006

(30) Foreign Application Priority Data
Jul. 20, 2005 (KR) 10-2005-0065799

(51) Int. Cl. H01L 23/02

(52) U.S. Cl. 257/686

(57) ABSTRACT

A planar light source includes a first substrate, a second substrate disposed to be spaced apart from the first substrate so as to form a discharge region, a first electrode formed on the first substrate, and a second electrode formed on the second substrate. The planar light source further includes a thermal conductive material which is laid on at least one of the first electrode and the second electrode.

### CROSS-REFERENCE TO RELATED APPLICATION

This application claims priority to Korean Patent Application No. 10-2005-0065799 filed on Jul. 20, 2005, the disclosure of which is hereby incorporated by reference herein in its entirety.

### BACKGROUND OF THE INVENTION

(a) Technical Field

The present disclosure relates to a planar light source device and a display device provided with the same. More particularly, the present disclosure relates to a planar light source device that is capable of preventing a pinhole phenomenon from occurring in an electrode thereof and a display device provided with the same.

(b) Description of the Related Art

Recently, with the rapidly developing semiconductor technology, the demand for display devices having improved performance has likewise significantly increased.

For example, such display devices include, for example, a liquid crystal display (LCD), a plasma display device (PDP), and an organic light emitting diode (OLED) display.

The volume and weight of the above-mentioned display devices are relatively small, but they can produce clear images. Thus, such display devices are gradually replacing conventional cathode ray tube (CRT) display technology, and are being utilized in various display devices such as, for example televisions (TVs), monitors, and mobile phones.

The liquid crystal display changes the molecular alignment of liquid crystal by applying a voltage to specifically align liquid crystal molecules. The liquid crystal display displays images using optical characteristic changes, which are caused by the change of the alignment of liquid crystal molecules, such as birefringence, optical rotary power, dichroism, and optical scattering characteristics. As such, the liquid crystal display displays images using the modulation of light by liquid crystal cells contained in a liquid crystal panel.

As the liquid crystal display uses a non-emissive type of display panel that does not emit light by itself, the liquid crystal display has a backlight assembly for supplying light to a rear surface of the display panel. Moreover, as a plurality of lamps are used in the backlight assembly of a large liquid crystal display such as a digital TV, there may be a difficulty encountered in that several parts are used so that the assembly process may become complicated. In addition, as the thickness of the backlight assembly is increased to prevent damage to fragile lamps by external impact, another difficulty may be encountered in that the overall thickness of the liquid crystal display may be increased.

To prevent the above-mentioned difficulties from occurring, a planar light source device including gas injected therein and emitting light by discharging the gas is being developed. With this planar light source device, electrodes are formed in the planar light source device. The gas injected in the planar light source device is discharged by applying a voltage to the electrodes. Ultraviolet rays emitted from discharged gas excite a phosphor layer, thereby generating a visible ray. Accordingly, light is emitted from the planar light source device.

Furthermore, if the electrode is formed outside the planar light source device, then parallel driving is possible and a voltage deviation between channels can be decreased. Therefore, many methods for forming the electrode outside the planar light source device are being developed.

However, if the electrode is driven by a high current at a high temperature, heating by pre-breakdown conduction current of a dielectric layer may occur. Thus, as a destructive voltage of the dielectric layer decreases, an overcurrent may flow at a threshold point. Consequently, pinholes are generated by the overcurrent at the substrate and the electrode of the planar light source device. Also, as the discharge gas that is closed and sealed within the planar light source device may leak under the generation of the pinholes, a difficulty may occur in that the planar light source device may not be able to operate under the pinholes.

Thus, there is a need for a planar light source device that is capable of preventing a pinhole phenomenon from occurring in an electrode thereof and a display device provided with the same.

### SUMMARY OF THE INVENTION

In accordance with an exemplary embodiment of the present invention, a planar light source device includes a first substrate, a second substrate disposed to be spaced apart from the first substrate so as to form a discharge region, a first electrode formed on the first substrate, and a second electrode formed on the second substrate.

The planar light source device further includes a thermal conductive material laid on at least one of the first electrode and the second electrode.

The thermal conductive material may be laid, for example, only on the electrode of the first and second electrodes in which more current flows while the planar light source device operates.

The thickness of the first substrate may be less than a thickness of the second substrate.

The thermal conductive material may be laid only on the second electrode.

The thermal conductive material may include aluminum oxide (Al₂O₃).

The area of the second electrode may be wider than an area of the first electrode.

The ratio of the area of the second electrode to the area of the first electrode may be about 2.0 to about 2.5.

The current density of the first electrode and a current density of the second electrode may be substantially equal to one another.

The planar light source device may further include dielectric layers respectively formed on an inner surface of the first substrate and an inner surface of the second substrate, and phosphor layers respectively covering each of the dielectric layers.

In accordance with an exemplary embodiment of the present invention, a display device includes a panel unit for displaying images, and a planar light source device for supplying light to the panel unit as stated above.

The display device further includes a thermal conductive material, which may be laid, for example, only on the electrode of the first and second electrodes in which more current flows while the planar light source device operates.

The thickness of the first substrate may be less than the thickness of the second substrate.

The thermal conductive material may be laid only on the second electrode.

The thermal conductive material may include Al₂O₃.

The area of the second electrode may be wider than an area of the first electrode.

The ratio of the area of the second electrode to the area of the first electrode may be about 2.0 to about 2.5.

The current density of the first electrode and a current density of the second electrode may be substantially equal to one another.

The planar light source device included in the display device according to an exemplary embodiment of the present invention may further include dielectric layers respectively formed on an inner surface of the first substrate and an inner surface of the second substrate, and phosphor layers respectively covering each of the dielectric layers.

The panel unit may be a liquid crystal panel.

### BRIEF DESCRIPTION OF THE DRAWINGS

FIG. 1 is a schematic perspective view of a planar light source device according to a first exemplary embodiment of the present invention.

FIG. 2 is a cross-sectional view taken along a line II-II in FIG. 1.

FIG. 3 is a cross-sectional view of a planar light source device according to a second exemplary embodiment of the present invention.

FIG. 4 is a cross-sectional view of a planar light source device according to a third exemplary embodiment of the present invention.

FIG. 5 is a cross-sectional view of a planar light source device according to a fourth exemplary embodiment of the present invention.

FIG. 6 is a cross-sectional view of a planar light source device according to a fifth exemplary embodiment of the present invention.

FIG. 7 is an exploded perspective view of a display device provided with the planar light source device according to the first exemplary embodiment of the present invention.

FIG. 8 is a driving block diagram of a panel unit included in the display device of FIG. 7.

FIG. 9 is an equivalent circuit diagram for one pixel of the panel unit.

### DETAILED DESCRIPTION OF THE EXEMPLARY EMBODIMENTS

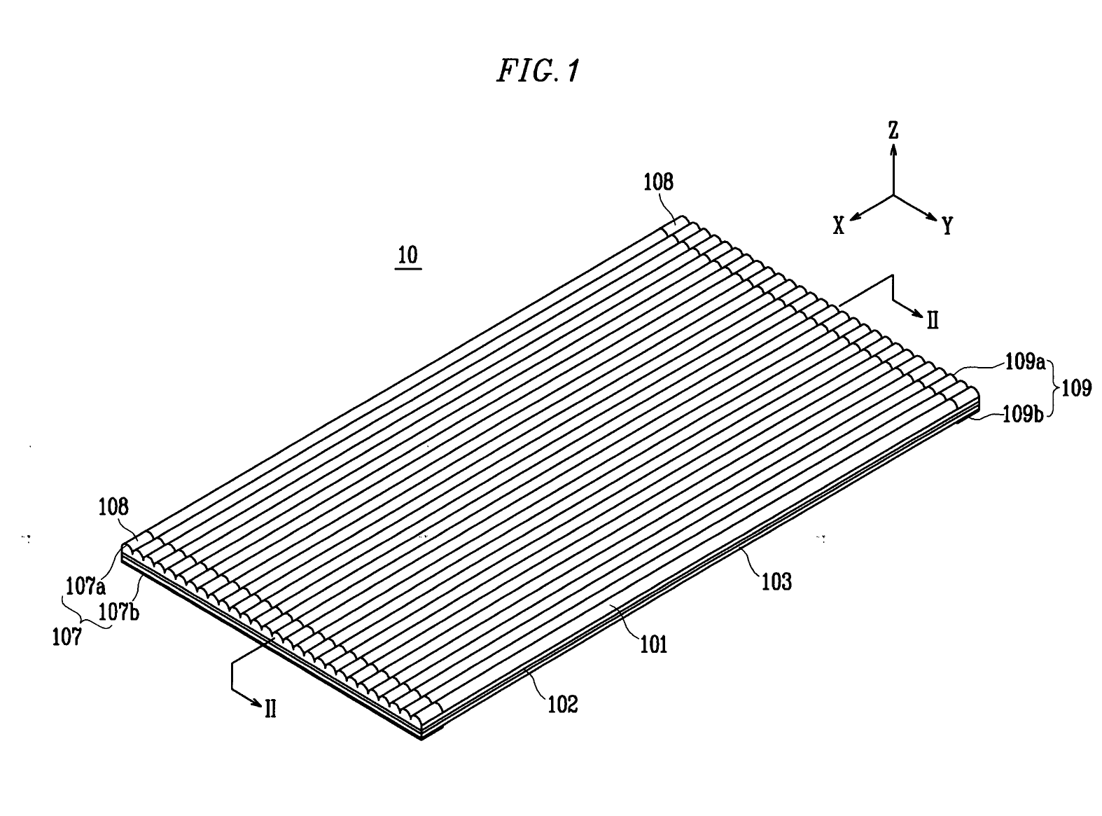

Exemplary embodiments of the present invention will hereinafter be described in detail with reference to FIGS. 1 to 9. The exemplary embodiments of the present invention exemplarily describe the present invention, and the present invention is not limited thereto.

FIG. 1 schematically shows a planar light source device 10 according to an exemplary embodiment of the present invention. The structure of the planar light source device 10 shown in FIG. 1 is an example of the present invention, and the present invention is not limited thereto. Thus, the planar light source device 10 may be changed to a different structure.

As shown in FIG. 1, an outer portion of the planar light source device 10 is covered by substrates 101 and 103. The substrates 101 and 103 are made of a glass material. The substrates 101 and 103 include a first substrate 101 and a second substrate 103. The second substrate 103 is installed to be apart from the first substrate 101, thereby forming a discharge region. The first substrate 101 and the second substrate 103 are attached to one another by frit 102.

The electrodes 107 and 109 are divided into positive electrodes 107a and 107b and negative electrodes 109a and 109b. The first electrodes 107a and 109a are formed on outer end portions of the first substrate 101. The second electrodes 107b and 109b are formed on outer end portions of the second substrate 103. A voltage is applied to the electrodes 107 and 109 so as to discharge the discharge gas within the planar light source device 10. The electrodes 107 and 109 are connected to wiring so as to be applied with an external voltage.

The first electrodes 107a and 109a are formed on the first substrate 101, and the second electrodes 107b and 109b are formed on the second substrate 103. A thermal conductive material 108 is laid on the first electrodes 107a and 109a. The thermal conductive material 108 is also laid on the second electrodes 107b and 109b.

By laying the thermal conductive material 108 on the electrodes 107 and 109, heat generated in the substrates 101 and 103 can be radiated to the outside. Accordingly, the pinhole phenomenon caused by flowing an overcurrent in the substrates 101 and 103 and the electrodes 107 and 109 can be prevented.

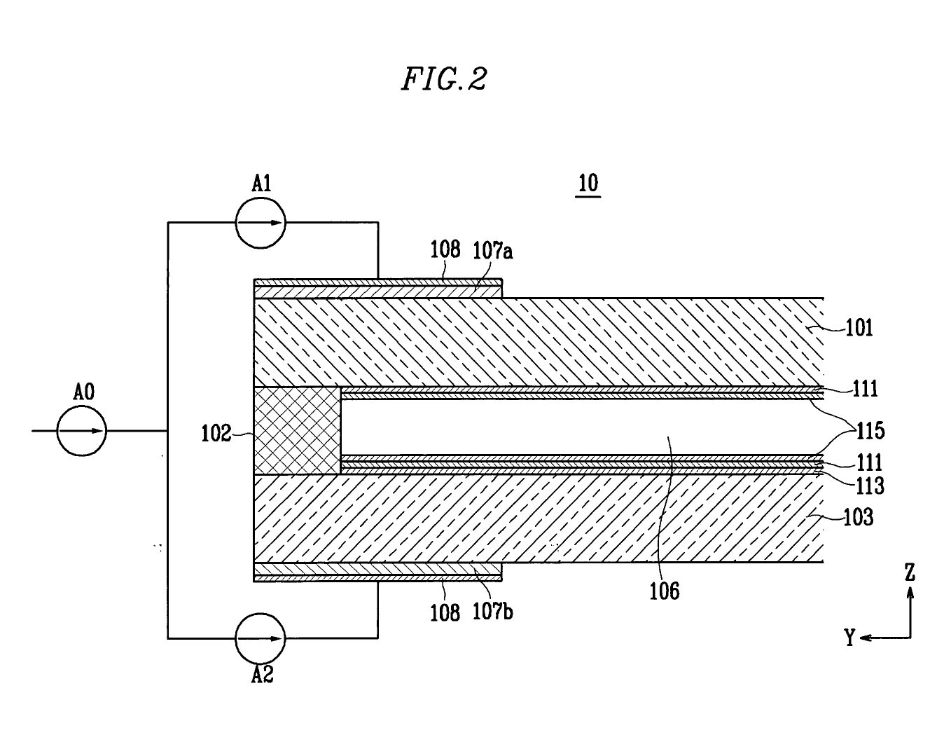

FIG. 2 shows a cross-sectional view of the planar light source device 10 taken along the line II-II in FIG. 1. Although the thermal conductive material 108 is laid on both the first electrode 107a and the second electrode 107b in FIG. 2, the exemplary embodiments of the present invention are not limited thereto. Thus, it is sufficient that the thermal conductive material is laid on at least one of the first electrode 107a and the second electrode 107b.

A compound including aluminum oxide (Al₂O₃) may be used as the thermal conductive material. A material including Al₂O₃ may be formed on the electrode using a method such as, for example, sputtering or spray coating.

An inner space of the planar light source device 10 is filled with an inert gas such as, for example xenon (Xe) or argon (Ar). A current A₀ is supplied to the electrodes 107a and 107b by a voltage applied from the outside. The current A₀ is divided into current A₁ supplied to the first electrode 107a and current A₂ supplied to the second electrode 107b. If current flows in the electrodes 107a and 107b, electrons are emitted so that discharge occurs. Ultraviolet rays are generated by the discharge, and the ultraviolet rays excite a phosphor layer 115. As the phosphor layer 115 disposed above the planar light source device 10 is transparent, light can be upwardly emitted. In addition, a reflection layer 113 formed of, for example, silver (Ag), is formed below the planar light source device 10, and the reflection layer 113 reflects light downwardly emitted from the planar light source device 10 in an upward direction. Accordingly, loss of light can be minimized to thereby improve luminance.

The planar light source device 10 includes a plurality of dividing walls 106. The plurality of dividing walls 106 partition an inner space of the planar light source device 10 so as to form a plurality of channels. Meanwhile, to prevent the electrodes 107a and 107b from being damaged by electrons emitted from the electrodes 107a and 107b, a dielectric layer 111 is formed. The electrodes 107a and 107b are protected using the dielectric layer 111. The dielectric layer 11 may be formed by mixing, for example, lead oxide (PbO), boron oxide (B₂O₃), silicon dioxide (SiO₂), zinc oxide (ZnO).

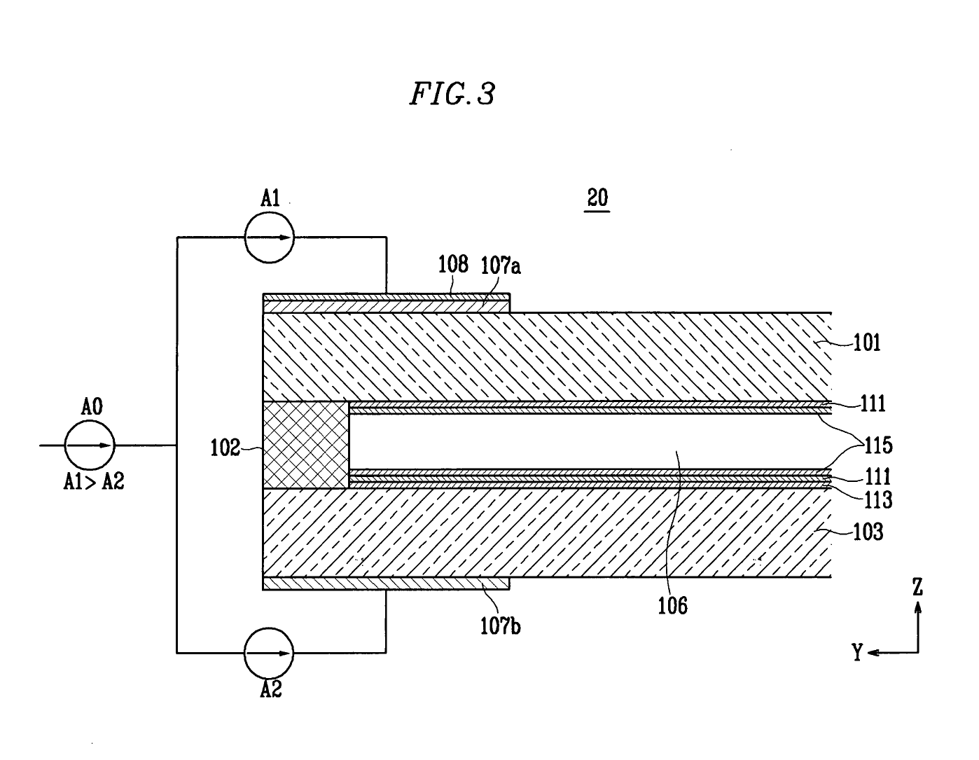

FIG. 3 shows a cross-sectional structure of a planar light source device 20 according to a second exemplary embodiment of the present invention. As the cross-sectional structure of the planar light source device 20 according to the second exemplary embodiment of the present invention shown in FIG. 3 is similar to the cross-sectional structure of the planar light source device according to the first exemplary embodiment of the present invention, the same reference numerals are used for the same elements, and detailed description thereof will be omitted.

In the planar light source device 20 according to the second exemplary embodiment of the present invention shown in FIG. 3, the thermal conductive material 108 is laid only on the first electrode 107a. When the planar light source device 20 operates, amounts of currents A₁ and A₂ respectively flowing in the electrodes 107a and 107b are different from each other. That is, A₁ is greater than A₂. Such a difference in the amount of current is caused by the difference in physical properties of the first substrate 101 and the second substrate 103. Thus, an overcurrent may flow in the first electrodes 107a and 107b. The first substrate 101 may be partially overheated by the overcurrent, thereby resulting in a pinhole phenomenon occurring. Thus, to prevent the above-mentioned pinhole phenomenon that is caused by overheating, the thermal conductive material 108 is laid on the first electrode 107a. As heat can be readily radiated through the thermal conductive material 108 even when the first substrate 101 is overheated, the durability of the planar light source device 20 is improved.

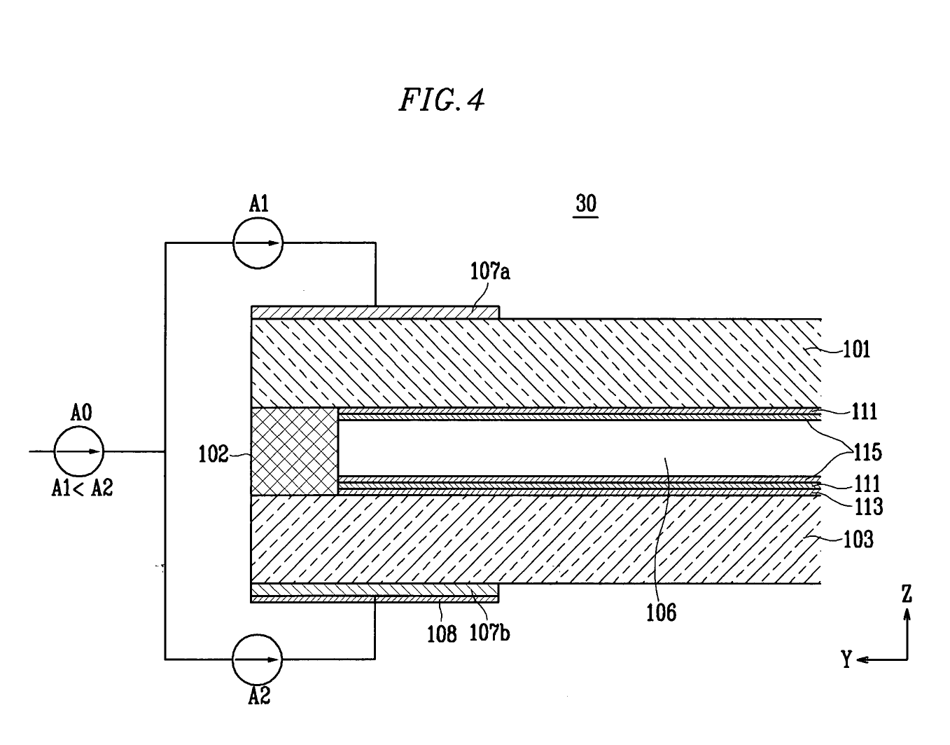

FIG. 4 shows a cross-sectional structure of a planar light source device 30 according to a third exemplary embodiment of the present invention. As the inner structure of the planar light source device 30 according to the third exemplary embodiment of the present invention shown in FIG. 4 is similar to the structure of the planar light source device according to the first exemplary embodiment of the present invention, the same reference numerals are used for the same elements, and detailed description thereof will be omitted.

Unlike the planar light source device according to the second exemplary embodiment of the present invention, in the planar light source device 30 according to the third exemplary embodiment of the present invention, the thermal conductive material 108 can be formed on the second electrode 107b. That is, as A₂ is greater than A₁, an overcurrent flows to the second substrate 103. To prevent pinholes from being generated in the second substrate 103 and the second electrode 107b because of the partial overcurrent, the thermal conductive material 108 is laid on the second electrode 107b. Thereby, the generation of pinholes can be prevented. For example, if a material having a high secondary electron emission coefficient such as Al₂O₃ is used as the thermal conductive material, the amount of secondary electrons emitted from the second substrate 103 is greater than amount of secondary electrons emitted from the first substrate 101. Accordingly, the amount of current A₂ flowing in the second substrate 103 becomes greater than the amount of current A₁ flowing in the first substrate 101.

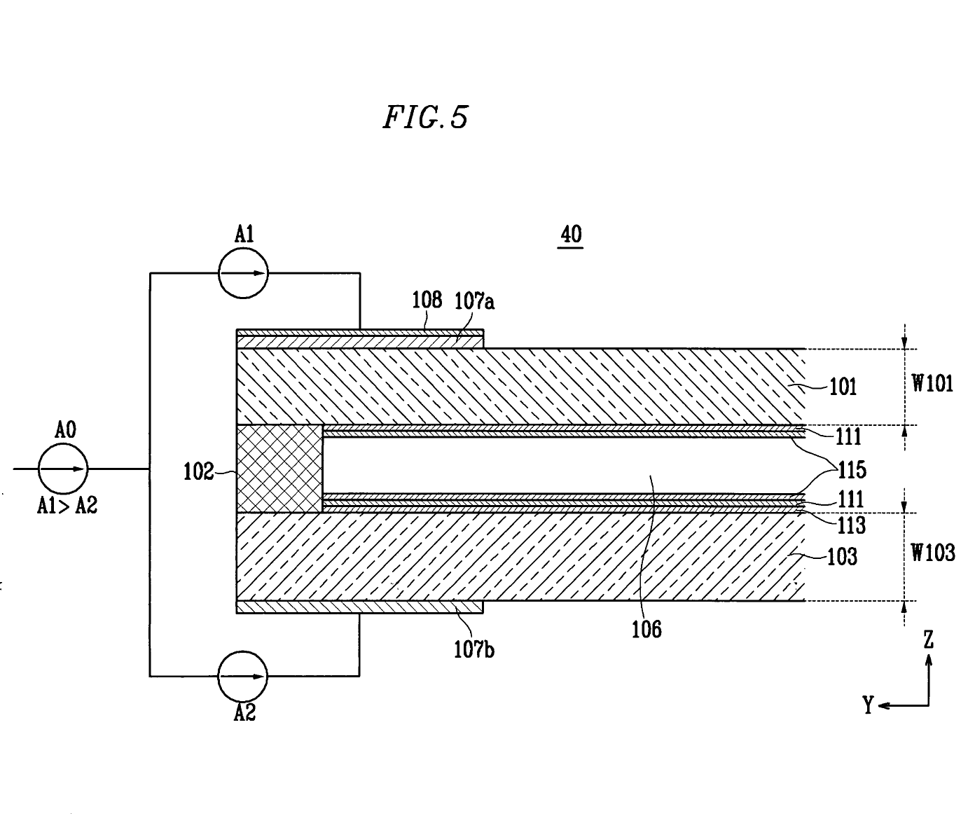

FIG. 5 shows a cross-sectional structure of a planar light source device 40 according to a fourth exemplary embodiment of the present invention. As shown in FIG. 5, the thickness W₁₀₁ of the first substrate 101 is formed to be less than the thickness W₁₀₃ of the second substrate 103. The first substrate 101 may be formed of glass. The first substrate 101 is formed using a glass forming process to simplify the process, to maintain vacuum conditions, to obtain a discharge space, and to decrease weight. To simply the process conditions and to improve process efficiency, the thickness W₁₀₁ of the first substrate 101 is formed to be less than the thickness W₁₀₃ of the second substrate 103. As the thickness of the first substrate 101 is less than that of the second substrate 103, the capacitance of the first substrate 101 is greater than the capacitance of the second substrate 103, so that more current flows in the first substrate 101. Although the temperature of the first electrode 107a becomes higher because of the current, the heat can be efficiently radiated because the thermal conductive material 108 is provided. Accordingly, degradation of the first electrode 107a can be prevented. As the degradation of the first electrode 107a is prevented, the generation of pinholes is also prevented.

For example, to decrease the luminance saturation time of the planar light source device at a low temperature, the planar light source device should be operated under the overcurrent state. Accordingly, as the overcurrent should inevitably be used, the planar light source device having the structure capable of preventing pinholes by the overcurrent should be used as well. By laying the thermal conductive material 108, the pinholes can be prevented and the luminance saturation time of the planar light source device can be decreased.

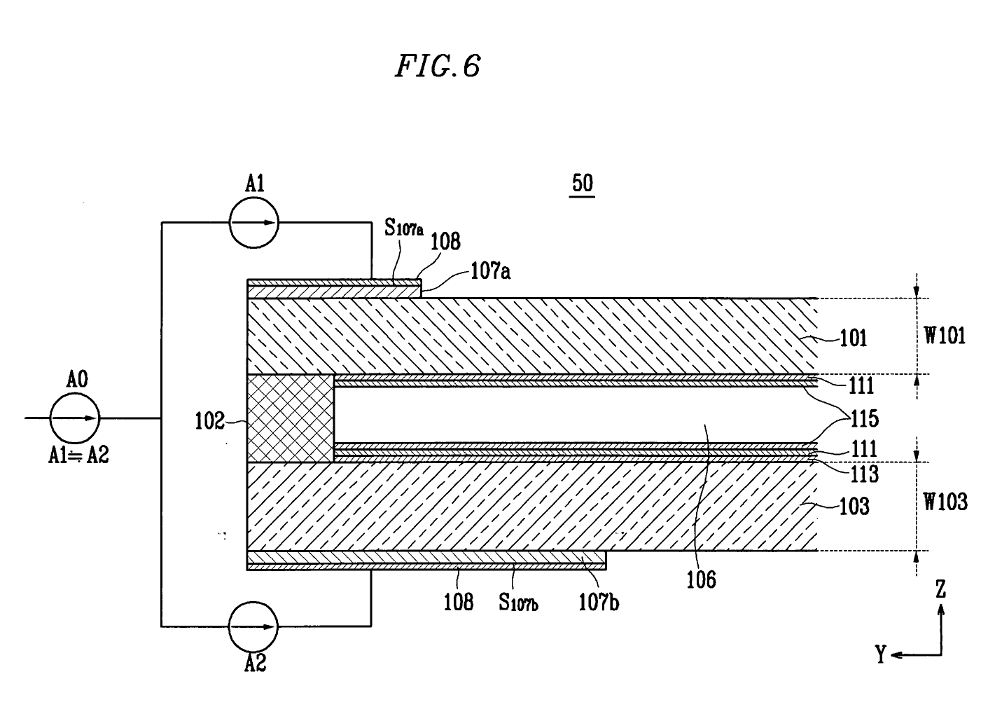

FIG. 6 shows a cross-sectional structure of a planar light source device 50 according to a fifth exemplary embodiment of the present invention. As the planar light source device 50 according to the fifth exemplary embodiment of the present invention shown in FIG. 6 is similar to the planar light source device according to the fourth exemplary embodiment of the present invention, the same reference numerals are used for the same elements, and detailed description thereof will be omitted.

As shown in FIG. 6, an area S_{107b} of the second electrode 107b is formed to be wider than an area S₁₀₇ₐ of the first electrode 107a. Here, the area is an area of the region facing the substrate. As the thickness W₁₀₁ of the first substrate 101 is less than the thickness W₁₀₃ of the second substrate 103, the capacitance of the first substrate 101 is greater than the capacitance of the second substrate 103. Here, the ratio of the capacitance of the first substrate 101 to the capacitance of the second substrate 103 is about 2.0 to about 2.5. Accordingly, the amount of current flowing to the first electrode 107a is relatively greater than the amount of current flowing to the second electrode 107b. Therefore, to compensate for this, the area S_{107b} of the second electrode 107b is formed to be wider than the area S₁₀₇ₐ of the first electrode 107a. Accordingly, the first electrode 107a and the second electrode 107b have substantially equal current densities.

As the capacitance is proportional to the area of the electrode, the area of the electrode is formed to be inversely proportional to the capacitance to obtain uniform capacitance. The ratio of the area S_{107b} of the second electrode 107b to the area S₁₀₇ₐ of the first electrode 107a is regulated to be about 2.0 to about 2.5. If the ratio of the areas is less than about 2.0, an overcurrent still flows to the first electrode 107a so that pinholes may be easily generated. On the other hand, if the ratio of the areas is greater than about 2.5, the overcurrent may flow to the second electrode 107b. In addition, as the thermal conductive material 108 is attached to the first electrode 107a and the second electrode 107b, heat can be effectively radiated to the outside.

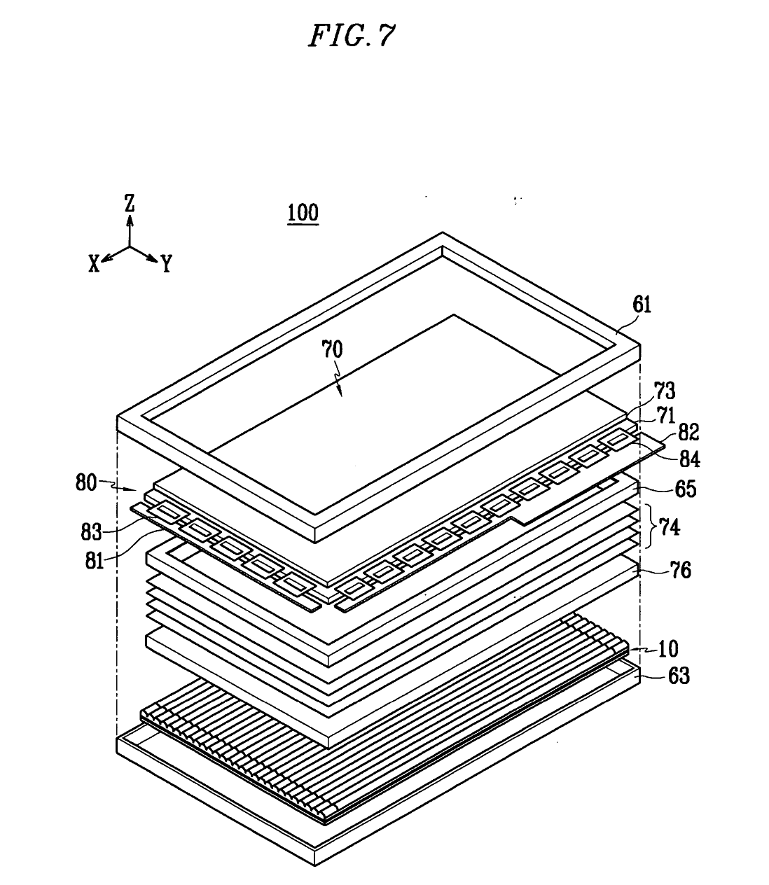

FIG. 7 shows a display device 100 provided with the planar light source device 10 shown in FIG. 1. The display device 100 shown in FIG. 7 exemplifies the present invention, and the present invention is not limited thereto. Therefore, the display device 100 can be changed to a different shape. In addition, although FIG. 7 shows that the display device includes the planar light source device 10 according to the first exemplary embodiment of the present invention, this exemplifies the present invention, and the present invention is not limited thereto. Thus, the display device 100 may include the planar light source device according to the second to fifth exemplary embodiments of the present invention as well.

The planar light source device 10 is mounted on a bottom chassis 63. An inverter is provided on a rear surface of the bottom chassis 63. The inverter changes external electric power to a constant level and then supplies the changed electric power to the planar light source device 10. The planar light source device 10 is connected to the inverter through a wire.

Light emitted from the planar light source device 10 is uniformly diffused while passing a diffuser 76. To make the luminance uniform, the planar light source device 10 is spaced apart from the diffuser 76 by a predetermined distance. Light that is uniformly diffused while passing the diffuser 76 obtains a linear movement characteristic while passing a plurality of optical sheets 74. As each optical sheet 74 includes a prism sheet, the optical sheet 74 makes light linearly progress. Accordingly, the luminance of light can be improved. The optical sheet 74 and the diffuser 76 can be fixed using a middle chassis 65. In addition, the middle chassis 65 supports a panel unit assembly 80 disposed thereabove.

Light is supplied to the panel unit 70, and the panel unit 70 displays images. Although a liquid crystal panel is shown as the panel unit 70 in FIG. 7, this exemplifies the present invention, and the present invention is not limited thereto. Thus, other light-receiving panels can be used.

The panel unit assembly 80 can be fixed by being covered by a top chassis 61. The panel unit assembly 80 includes a panel unit 70, driving IC (integrated circuit) packages 83 and 84, and printed circuit boards 81 and 82. A COF (chip on film), a TCP (tape carrier package), or the like can be used as the driving IC package. The printed circuit boards 81 and 82 may be housed in a side surface of another frame member 19.

The panel unit 70 includes a TFT (thin film transistor) panel 71 constituted by a plurality of TFTs, a color filter panel 73 disposed above the TFT panel 71, and a liquid crystal interposed therebetween. A polarizer for polarizing light passing the panel unit 70 is attached to an upper surface of the color filter panel 73 and a lower surface of the TFT panel 71.

The TFT panel 71 is a transparent glass substrate on which thin film transistors are formed in a matrix shape, a data line is connected to a source terminal, and a gate line is connected to a gate terminal. A pixel electrode made of transparent ITO (indium tin oxide) as a conductive material is formed to a drain terminal.

If electrical signals are input to the gate line and the date line of the panel unit 70 from the printed circuit boards 81 and 82, electrical signals are input to the gate terminal and the source terminal of the TFT, and the TFT is turned on or turned off according to these input electrical signals so that electrical signals needed for forming pixels are output to the drain terminal.

Meanwhile, a color filter panel 73 is disposed on the TFT panel 71 such that they face one another. The color filter panel 73 is a panel having RGB pixels, which are color pixels for generating predetermined colors while light passes therethrough, and is formed by a thin film process. A common electrode made of ITO is formed on an entire surface of the color filter panel 73. If electrical power is applied to the gate terminal and the source terminal of the TFT, the TFT is turned on, and thereby an electric field is generated between the pixel electrode and the common electrode of the color filter panel. This electric field changes an arrangement angle of liquid crystal interposed between the TFT panel 71 and the color filter panel 73, and light transmittance is changed depending on the changed arrangement angle to thereby obtain a desired display.

The printed circuit boards 81 and 82 receiving image signals from the outside of the panel unit 70 and respectively applying driving signals to the gate line and the data line are connected to each of the driving IC packages 83 and 84 attached to the panel unit 70. To drive the display device 100, the gate printed circuit board 81 transmits gate driving signals, and the data printed circuit board 82 transmits data driving signals. That is, the gate driving signals and the data driving signals are applied to the gate line and the data line of the panel unit 70 through each of the driving IC packages 83 and 84. A control board is mounted on a rear surface of the backlight assembly 10. The control board is connected to the data printed circuit board 82, and converts an analog data signal to a digital data signal and supplies the converted signal to the panel unit 70.

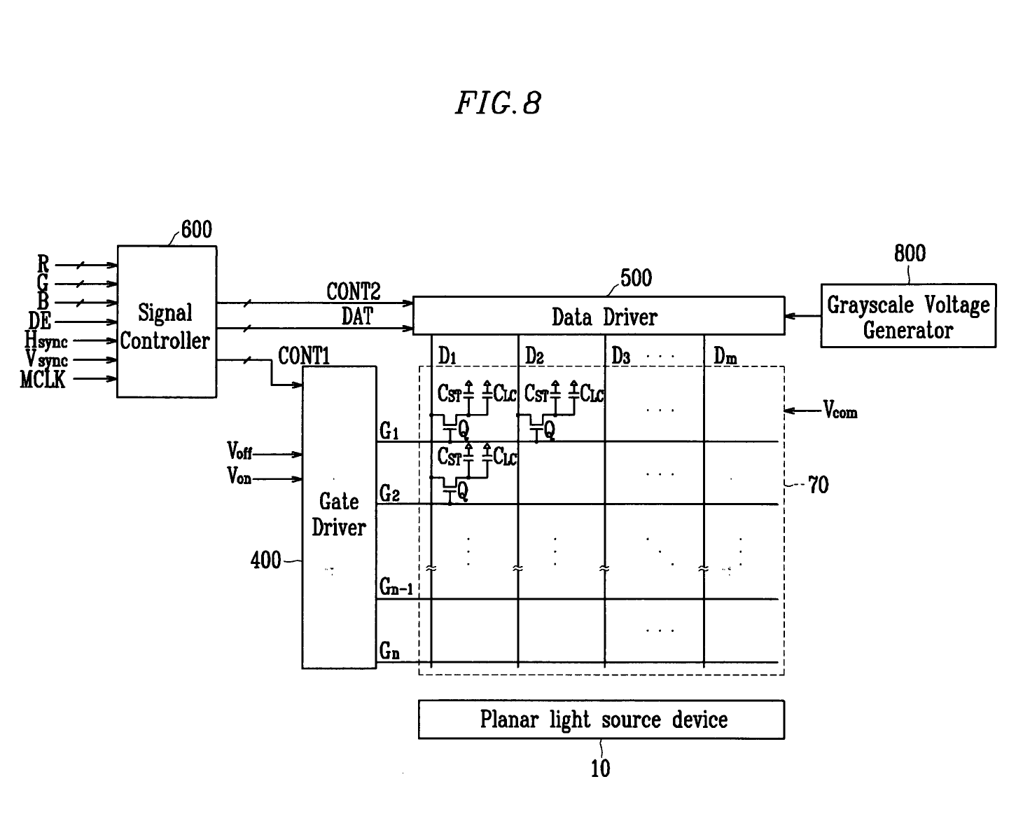

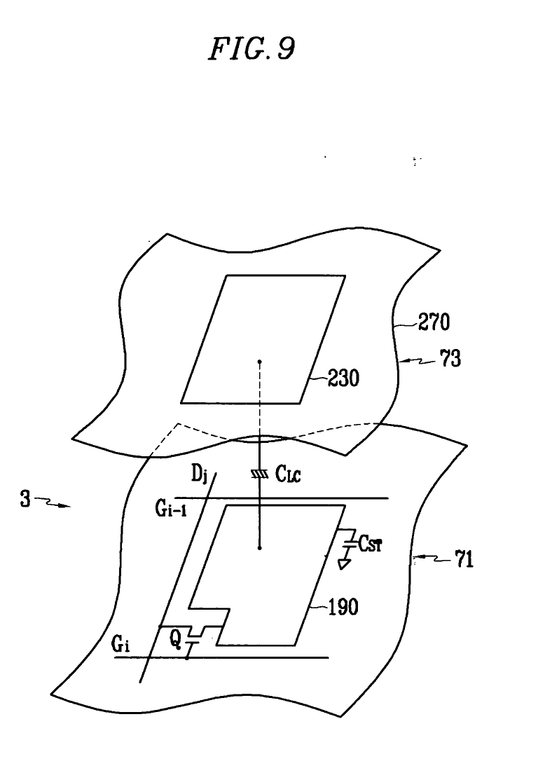

Hereinafter, referring to FIGS. 8 and 9, the operation of the panel unit 70 will be explained in detail.

The TFT panel 71 includes a plurality of display signal lines G₁ to Gₙ and D₁ to Dₘ. The color filter panel 73 and the TFT panel 71 are connected to the display signal lines G₁ to Gₙ and D₁ to Dₘ, and include a plurality of pixels substantially arranged in a matrix shape. The display signal lines G₁ to Gₙ and D₁ to Dₘ include a plurality of gate lines G₁ to Gₙ for transmitting gate signals (also referred to as scanning signals) and data lines D₁ to Dₘ for transmitting data signals. The gate lines G₁ to Gₙ substantially extend in a row direction to be parallel to one another, and the data lines D₁ to Dₘ substantially extend in a column direction to be parallel to one another.

Each pixel includes a switching element Q connected to the display signal lines G₁ to Gₙ and D₁ to Dₘ, and a liquid crystal capacitor C_{LC} and a storage capacitor C_{ST} each connected to the switching element Q. In other exemplary embodiments, the storage capacitor C_{ST} can be omitted.

The switching element Q such as, for example, a thin film transistor is provided to the TFT panel 71, and is a 3-terminal element. A control terminal and an input terminal of the switching element Q are connected to the gate lines G₁ to Gₙ and the data lines D₁ to Dₘ, respectively, and an output terminal thereof is connected to the liquid crystal capacitor C_{LC} and the storage capacitor C_{ST}.

The liquid crystal capacitor C_{LC} has two terminals of a pixel electrode 190 of the TFT panel 71 and a common electrode 270 of the color filter panel 73, and the liquid crystal layer 3 between the two electrodes 190 and 270 serves as a dielectric material. The pixel electrode 190 is connected to the switching element Q. The common electrode 270 is formed on the entire surface of the color filter panel 73, and a common voltage V_{com} is applied to the common electrode 270. Alternatively, the common electrode 270 may be provided on the TFT panel 71. In this case, at least one of the two electrodes 190 and 270 can be formed in a linear or bar shape.

The storage capacitor C_{ST}, which assists the liquid crystal capacitor C_{LC}, has a separate signal line provided on the TFT panel 71 and the pixel electrode 190 to overlap each other with an insulator therebetween. A fixed voltage such as the common voltage Vcom is applied to the separate signal line. However, the storage capacitor C_{ST} may be formed by the pixel electrode 190 and the overlying previous gate lines that are arranged to overlap each other through an insulator.

The signal controller 600 receives input image signals R, G, and B and input control signals for controlling display of the input image signals R, G, and B, such as for example a vertical synchronization signal Vsync, a horizontal synchronizing signal Hsync, a main clock signal MCLK, or a data enable signal DE, from an external graphics controller. The signal controller 600 processes the image signals R, G, and B according to the operating condition of the liquid crystal panel assembly 300 on the basis of the input image signals R, G, and B and the input control signals, and generates a gate control signal CONT1 and a data control signal CONT2. Then, the signal controller 600 supplies the gate control signal CONT1 to the gate driver 400 and supplies the data control signal CONT2 and the processed image signal DAT to the data driver 500.

The gate control signal CONT1 includes a scanning start signal STV for instructing to start output of a gate-on voltage Vₒₙ, at least one clock signal for controlling an output time, and an output voltage of a gate-on voltage Vₒₙ.

The data control signal CONT2 includes a horizontal synchronization start signal STH for notifying start of transmission of image data DAT, a load signal LOAD for instructing to apply the data voltage to data lines D₁ to Dₘ, an inversion signal RVS for inverting the polarity of the data voltage relative to the common voltage V_{com} (hereinafter, the polarity of the data voltage relative to the common voltage is simply referred to as the polarity of the data voltage), and a data clock signal HCLK.

The signal controller 600 may transmit a control signal for controlling the operation of the backlight assembly 10, a clock signal, or the like, to the backlight assembly 10, in addition to the control signals CONT1 and CONT2.

The data driver 500 sequentially receives image data DAT for one row of pixels according to the data control signal CONT2 from the signal controller 600 and shifts the same, and selects the gray voltage corresponding to each image data among gray voltages from a gray voltage generator 800. Then, the data driver 500 converts image data DAT into the corresponding data voltage, and applies the data voltage to the data lines D₁ to Dₘ.

The gate driver 400 applies the gate-on voltage Vₒₙ to the gate lines G₁ to Gₙ on the basis of the gate control signal CONT1 from the signal controller 600 so as to turn on the switching element Q connected to the gate lines G₁ to Gₙ. Accordingly, the data voltage applied to the data lines D₁ to Dₘ is applied to the corresponding pixel through the turned-on switching element Q.

The difference between the data voltage applied to the pixel and the common voltage V_{com} becomes a charge voltage of the liquid crystal capacitor C_{LC}, that is, a pixel voltage. The alignment of liquid crystal molecules varies according to the value of the pixel voltage.

The data driver 500 and the gate driver 400 repeat the same operations for every one horizontal period (or “1H”) (one cycle of the horizontal synchronizing signal Hsync) for pixels of the following row. In such a manner, the gate-on voltage Vₒₙ is applied to all of the gate lines G₁ to Gₙ for one frame, and the data voltage is applied to all of the pixels. If one frame is completed and a next frame starts, the state of the inversion signal RVS to be applied to the data driver 500 is controlled such that the polarity of the data voltage to be applied to each pixel is opposite to the polarity thereof in the previous frame (“frame inversion”). At this time, the polarity of the data voltage on one data line may be changed in one frame according to the characteristics of the inversion signal RVS (row inversion or dot inversion) or the polarities of the data voltage applied to one pixel row may be different from each other (column inversion or dot inversion).

Hereinafter, experimental examples of the present invention will be explained. The experimental examples of the present invention represent exemplary embodiments of the present invention, and the present invention is not limited thereto.

### EXPERIMENTAL EXAMPLES

Experimentation was performed for the planar light source device shown in FIG. 1 for a 42 inch LCD TV. The planar light source device had 28 channels. The planar light source device in which the external electrode is coated by Al₂O₃ is connected to an electric power source, and the voltage is applied. Experimentation was performed while the applied voltage was gradually increased.

### Experimental Example 1

After coating A₂O₃ on both the upper electrode and the lower electrode of the planar light source device, a voltage was applied. The total amount of current A0 in applying the voltage was about 0.80 A. The amount of current A₁ flowing in the upper electrode and the amount of current A₂ flowing in the lower electrode were respectively measured, and current densities J₁ and J₂ were calculated. Here, the current density J₁ is a value obtained by dividing the amount of current flowing in the upper electrode by the area of the upper electrode (cm²). The current density J₂ is a value obtained by dividing the amount of the current flowing in the lower electrode by the area of the lower electrode (cm²). Then, the ratio of the current densities J₁/J₂ was calculated.

### Experimental Example 2

The total amount of current A₀ in applying the voltage was about 0.85 A. The other experimental conditions were the same as those of Experimental Example 1.

### Experimental Example 3

The total amount of current A₀ in applying the voltage was about 0.90 A. The other experimental conditions were the same as those of Experimental Example 1.

### Experimental Example 4

The total amount of current A₀ in applying the voltage was about 0.95 A. The other experimental conditions were the same as those of Experimental Example 1.

### Experimental Example 5

The total amount of current A₀ in applying the voltage was about 1.00 A. The other experimental conditions were the same as those of Experimental Example 1.

### Experimental Example 6

The total amount of current A₀ in applying the voltage was about 1.05 A. The other experimental conditions were the same as those of Experimental Example 1.

### Experimental Example 7

The total amount of current A₀ in applying the voltage was about 1.10 A. The other experimental conditions were the same as those of Experimental Example 1.

### Experimental Example 8

The total amount of current A₀ in applying the voltage was about 1.14 A. The other experimental conditions were the same as those of Experimental Example 1.

### Experimental Example 9

After coating A₂O₃ on only the lower electrode of the planar light source device, a voltage was applied to the planar light source device. The total amount of current A₀ in applying the voltage was about 0.81 A. The amount of current A₁ flowing in the upper electrode and the amount of current A₂ flowing in the lower electrode were respectively measured, and current densities J₁ and J₂ were calculated. In addition, the ratio of the current densities J₁/J₂ was calculated.

### Experimental Example 10

The total amount of current A₀ in applying the voltage was about 0.85 A. The other experimental conditions were the same as those of Experimental Example 9.

### Experimental Example 11

The total amount of current A₀ in applying the voltage was about 0.90 A. The other experimental conditions were the same as those of Experimental Example 9.

### Experimental Example 12

The total amount of current A₀ in applying the voltage was about 0.95 A. The other experimental conditions were the same as those of Experimental Example 9.

### Experimental Example 13

The total amount of current A₀ in applying the voltage was about 1.00 A. The other experimental conditions were the same as those of Experimental Example 9.

### Experimental Example 14

The total amount of current A₀ in applying the voltage was about 1.06 A. The other experimental conditions were the same as those of Experimental Example 9.

### Experimental Example 15

The total amount of current A₀ in applying the voltage was about 1.10 A. The other experimental conditions were the same as those of Experimental Example 9.

### Comparative Example

Experimentation was performed for the planar light source device according to comparative examples of the conventional art. Experimentation was performed for the planar light source device for a 42 inch LCD TV. The planar light source device had 28 channels. The planar light source device in which the external electrode was not coated by the thermal conductive material was connected to an electric power source, and the voltage was applied. Experimentation was performed while the applied voltage was gradually increased.

### Comparative Example 1

The total amount of current A₀ in applying the voltage was about 0.81 A. An amount of current A₁ flowing in the upper electrode and an amount of current A₂ flowing in the lower electrode were respectively measured, and current densities J₁ and J₂ were calculated. Then, a ratio of the current densities J₁/J₂ was calculated.

### Comparative Example 2

The total amount of current A₀ in applying the voltage was about 0.85 A. The other experimental conditions were the same as those of Comparative Example 1.

### Comparative Example 3

The total amount of current A₀ in applying the voltage was about 1.00 A. The other experimental conditions were the same as those of Comparative Example 1.

### Comparative Example 4

The total amount of current A₀ in applying the voltage was about 1.05 A. The other experimental conditions were the same as those of Comparative Example 1.

### Comparative Example 5

The total amount of current A₀ in applying the voltage was about 1.10 A. The other experimental conditions were the same as those of Comparative Example 1.

### Comparative Example 6

The total amount of current A₀ in applying the voltage was about 1.15 A. The other experimental conditions were the same as those of Comparative Example 1.

### Comparative Example 7

The total amount of current A₀ in applying the voltage was about 1.20 A. The other experimental conditions were the same as those of Comparative Example 1.

### Comparative Example 8

The total amount of current A₀ in applying the voltage was about 1.90 A. The other experimental conditions were the same as those of Comparative Example 1.

### Comparative Example 9

The total amount of current A₀ in applying the voltage was about 1.95 A. The other experimental conditions were the same as those of Comparative Example 1. Table 1 shows experimental results of the experimental examples and the comparative examples.

TABLE 1

| NO | A₀ | A₁ | A₂ | A₁/A₂ | J₁ | J₂ | J₁/J₂ |
|---|---|---|---|---|---|---|---|
| Experimental | 0.80 | 0.0621 | 0.0312 | 1.99 | 36.8 | 24.0 | 1.5 |
| Example 1 | | | | | | | |
| Experimental | 0.85 | 0.0663 | 0.0335 | 1.98 | 39.2 | 25.8 | 1.5 |
| Example 2 | | | | | | | |
| Experimental | 0.90 | 0.0707 | 0.0356 | 1.98 | 41.8 | 27.4 | 1.5 |
| Example 3 | | | | | | | |
| Experimental | 0.95 | 0.0749 | 0.0378 | 1.98 | 44.3 | 29.0 | 1.5 |
| Example 4 | | | | | | | |
| Experimental | 1.00 | 0.0792 | 0.0400 | 1.98 | 46.9 | 30.7 | 1.5 |
| Example 5 | | | | | | | |
| Experimental | 1.05 | 0.0843 | 0.0424 | 1.99 | 49.9 | 32.6 | 1.5 |
| Example 6 | | | | | | | |
| Experimental | 1.10 | 0.0891 | 0.0448 | 1.99 | 52.7 | 34.5 | 1.5 |
| Example 7 | | | | | | | |
| Experimental | 1.14 | 0.0937 | 0.0470 | 1.99 | 55.5 | 36.1 | 1.5 |
| Example 8 | | | | | | | |
| Experimental | 0.81 | 0.0535 | 0.0393 | 1.36 | 31.7 | 30.2 | 1.0 |
| Example 9 | | | | | | | |
| Experimental | 0.85 | 0.0567 | 0.0417 | 1.36 | 33.6 | 32.1 | 1.0 |
| Example 10 | | | | | | | |
| Experimental | 0.90 | 0.0603 | 0.0443 | 1.36 | 35.7 | 34.1 | 1.0 |
| Example 11 | | | | | | | |
| Experimental | 0.95 | 0.0639 | 0.0470 | 1.36 | 37.8 | 36.1 | 1.0 |
| Example 12 | | | | | | | |
| Experimental | 1.00 | 0.0680 | 0.0500 | 1.36 | 40.2 | 38.5 | 1.0 |
| Example 13 | | | | | | | |
| Experimental | 1.06 | 0.0725 | 0.0532 | 1.36 | 42.9 | 40.9 | 1.0 |
| Example 14 | | | | | | | |
| Experimental | 1.10 | 0.0770 | 0.0566 | 1.36 | 45.6 | 43.5 | 1.0 |
| Example 15 | | | | | | | |
| Comparative | 0.81 | 0.0648 | 0.0289 | 2.24 | 38.3 | 22.2 | 1.7 |
| Example 1 | | | | | | | |
| Comparative | 0.85 | 0.0679 | 0.0303 | 2.24 | 40.2 | 23.3 | 1.7 |
| Example 2 | | | | | | | |
| Comparative | 1.00 | 0.0718 | 0.0321 | 2.24 | 42.5 | 24.7 | 1.7 |
| Example 3 | | | | | | | |
| Comparative | 1.05 | 0.0759 | 0.0339 | 2.24 | 44.9 | 26.1 | 1.7 |
| Example 4 | | | | | | | |
| Comparative | 1.10 | 0.0802 | 0.0357 | 2.25 | 47.5 | 27.5 | 1.7 |
| Example 5 | | | | | | | |
| Comparative | 1.15 | 0.0842 | 0.0376 | 2.24 | 49.8 | 28.9 | 1.7 |
| Example 6 | | | | | | | |
| Comparative | 1.20 | 0.0885 | 0.0393 | 2.25 | 52.4 | 30.2 | 1.7 |
| Example 7 | | | | | | | |
| Comparative | 1.90 | 0.0924 | 0.0412 | 2.24 | 54.7 | 31.7 | 1.7 |
| Example 8 | | | | | | | |
| Comparative | 1.95 | 0.0963 | 0.0429 | 2.24 | 57.0 | 33.0 | 1.7 |
| Example 9 | | | | | | | |

As illustrated by Table 1, the ratios of the current densities in Experimental Examples 1 to 8 in which all external electrodes were coated by Al₂O₃ are about 1.5, and the ratios of the current densities in Comparative Examples 1 to 9 are about 1.7. It can be seen that the ratios of the current densities in Experimental Examples 1 to 8 decreased somewhat relative to the ratios of the current densities in Comparative Examples 1 to 9. In addition, when the current densities in Experimental Examples 9 to 15 in which Al₂O₃ was coated only on the lower electrode, the ratios of the current densities are about 1.0. Accordingly, from the results of Experimental Examples 9 to 15, it can be seen that the generation of the pinholes can be efficiently prevented by coating Al₂O₃ only on the lower electrode.

As can be seen from the experimental examples, in the exemplary embodiments of the present invention, the current density of the upper electrode and the current density of the lower electrode are similar or equal to each other. Accordingly, the pinholes generated in the electrode by an overcurrent can be prevented.

As described above, as a thermal conductive material is laid on the electrode in the planar light source device according to exemplary embodiments of the present invention, the pinholes generated in the electrode can be prevented.

As the thickness of the first substrate is less than the thickness of the second substrate, the first substrate is readily made by glass forming.

As the thermal conductive material includes Al₂O₃, heat can be further efficiently radiated.

As the area of the second electrode is wider than the area of the first electrode, the capacitance of the electrode is counterbalanced so that current can be uniformly distributed on both electrodes.

As the display device according to exemplary embodiments of the present invention uses the liquid crystal panel as a panel unit, the application process is relatively simple.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A planar light source device comprising:
a first substrate;
a second substrate disposed to be spaced apart from the first substrate so as to form a discharge region;
a first electrode formed on the first substrate; and
a second electrode formed on the second substrate,
wherein a thermal conductive material is laid on at least one of the first electrode and the second electrode.

2. The planar light source device of claim 1, wherein the thermal conductive material is laid only on the electrode of the first and second electrodes in which more current flows while the planar light source device operates.

3. The planar light source device of claim 1, wherein a thickness of the first substrate is less than a thickness of the second substrate.

4. The planar light source device of claim 3, wherein the thermal conductive material is laid only on the second electrode.

5. The planar light source device of claim 1, wherein the thermal conductive material includes aluminum oxide (Al₂O₃).

6. The planar light source device of claim 1, wherein an area of the second electrode is wider than an area of the first electrode.

7. The planar light source device of claim 6, wherein a ratio of the area of the second electrode to the area of the first electrode is about 2.0 to about 2.5.

8. The planar light source device of claim 1, wherein a current density of the first electrode and a current density of the second electrode are substantially equal to one another.

9. The planar light source device of claim 1, further comprising:
dielectric layers respectively formed on an inner surface of the first substrate and an inner surface of the second substrate; and
phosphor layers respectively covering each of the dielectric layers.

10. A display device comprising:
a panel unit for displaying images; and
a planar light source device for supplying light to the panel unit,
wherein the planar light source device comprises
a first substrate,
a second substrate disposed to be spaced apart from the first substrate so as to form a discharge region,
a first electrode formed on the first substrate, and
a second electrode formed on the second substrate,
and wherein a thermal conductive material is laid on at least one of the first electrode and the second electrode.

11. The display device of claim 10, wherein the thermal conductive material is laid only on the electrode of the first and second electrodes in which more current flows while the planar light source device operates.

12. The display device of claim 10, wherein a thickness of the first substrate is less than a thickness of the second substrate.

13. The display device of claim 12, wherein the thermal conductive material is laid only on the second electrode.

14. The display device of claim 10, wherein the thermal conductive material includes aluminum oxide (Al₂O₃).

15. The display device of claim 10, wherein an area of the second electrode is wider than an area of the first electrode.

16. The display device of claim 15, wherein a ratio of the area of the second electrode to the area of the first electrode is about 2.0 to about 2.5.

17. The display device of claim 10, wherein a current density of the first electrode and a current density of the second electrode are substantially equal to one another.

18. The display device of claim 10, wherein the planar light source device is further comprises:
dielectric layers formed on an inner surface of the first substrate and an inner surface of the second substrate; and
phosphor layers covering each of the dielectric layers.

19. The display device of claim 10, wherein the panel unit is a liquid crystal panel.
